(19) United States
(12) Patent Application Publication
(10) Pub. No.: US 2022/0283240 A1
(43) Pub. Date: Sep. 8, 2022

(54) METHOD AND SYSTEM FOR ESTIMATING STATE OF HEALTH OF BATTERY PACK

(71) Applicant: WUHAN UNIVERSITY, HUBEI (CN)

(72) Inventors: Yigang HE, Hubei (CN); Chaolong ZHANG, Hubei (CN); Shaishai Zhao, Hubei (CN); Liulu HE, Hubei (CN)

(73) Assignee: WUHAN UNIVERSITY, HUBEI (CN)

(21) Appl. No.: 17/504,528

(22) Filed: Oct. 19, 2021

(30) Foreign Application Priority Data
Mar. 4, 2021 (CN) 202110240005.1

(51) Int. Cl. G01R 31/392; G01R 31/367; G01R 31/3835; G01R 31/374; G06N 3/04; G06N 3/00; H02J 7/00

(52) U.S. Cl. CPC G01R 31/392; G01R 31/367; G01R 31/3835; G01R 31/374; G06N 3/0445; G06N 3/006; H02J 7/005

(57) ABSTRACT

The invention discloses a method and system for estimating an SOH of a battery pack, including: measuring an SOH data sequence of each charge and discharge cycle of a battery pack and a terminal voltage and a temperature data sequence of the battery pack of each charging stage; calculating voltage entropy and mean temperature data sequences of the battery pack with the charge and discharge cycle; performing an optimization option on a learning rate of a long short-term memory neural network using a particle swarm algorithm based on the voltage entropy, mean temperature and SOH data sequences of the battery pack with the charge and discharge cycle; establishing an SOH estimation model of the long short-term memory neural network using the learning rate obtained by the particle swarm optimization; and estimating the SOH of the battery pack using the established SOH estimation model of the long short-term memory neural network.

### CROSS-REFERENCE TO RELATED APPLICATION

This application claims the priority benefit of China application serial no.

202110240005.1, filed on Mar. 4, 2021. The entirety of the above-mentioned patent application is hereby incorporated by reference herein and made a part of this specification.

### BACKGROUND OF THE INVENTION

### Field of the Invention

The invention belongs to the technical field of batteries, and more specifically relates to a method and a system for estimating the state of health of a battery pack, and relates to reflecting the capacity degradation of a lithium battery pack via a voltage entropy and a mean temperature of a voltage data sequence of each charging stage, and estimating an SOH of the lithium battery pack using an SOH estimation model established by a long short-term memory neural network after optimization by a particle swarm algorithm based on the voltage entropy and the mean temperature.

### Description of Related Art

The built-in power battery system of a new energy vehicle is the bottleneck of the development of new energy vehicle techniques. The power battery pack is the energy supply of the entire vehicle, and the long-life operation thereof is essential to ensure the efficient operation of the entire vehicle. However, the storage capacity and the rapid charge and discharge capacity of the power lithium battery pack both continuously to decline with aging, and the SOH of the lithium battery pack is a quantitative indicator for evaluating the degree of battery aging. Therefore, it is very necessary to accurately estimate the SOH of the lithium battery pack.

The SOH of the lithium battery pack is generally characterized by battery capacity, and capacity data is obtained during continuous charge and discharge cycles. The data acquisition process thereof is inevitably affected by various factors, so that the SOH of the lithium battery pack may not be accurately estimated. Information entropy is a method of data statistics and analysis. Original data may be effectively reflected by calculating the information entropy of the data to characterize the uncertainty of the data. A long short-term memory neural network is a type of cyclic neural network, and is suitable for dealing with issues related to time sequence. The learning rate in the long short-term memory neural network has great influence on estimation error, and is usually obtained via empirical trial methods in the past.

### SUMMARY OF THE INVENTION

In view of the above defects or improvement requirements of the prior art, the invention provides a method and a system for estimating the state of health of a battery pack that may effectively reflect the degradation of the capacity of the lithium battery pack and accurately estimate the state of health of the lithium battery pack.

To achieve the above object, according to one aspect of the invention, a method for estimating a state of health of a battery pack is provided, including:

(1) measuring a state of health SOH data sequence and a characteristic data sequence of a lithium battery pack with a charge and discharge cycle, wherein the characteristic data sequence of the lithium battery pack with the charge and discharge cycle includes a change data of a terminal voltage and a temperature of a charging stage in each charge and discharge cycle;

(2) performing a statistical analysis on the change data of the terminal voltage and the temperature of the charging stage in each charge and discharge cycle, and calculating a voltage entropy data sequence and a mean temperature data sequence of the lithium battery pack with the charge and discharge cycle;

(3) executing an optimization option on a learning rate of a long short-term memory neural network using a particle swarm algorithm based on the voltage entropy data sequence, the mean temperature data sequence, and the SOH data sequence of the lithium battery pack with the charge and discharge cycle;

(4) establishing an SOH estimation model of the long short-term memory neural network using the learning rate obtained by the particle swarm optimization, in order to estimate an SOH of the lithium battery pack using the established SOH estimation model of the long short-term memory neural network.

In some alternative embodiments, step (1) includes:

the measured state of health data of the lithium battery pack is the SOH data of the lithium battery pack, a change data of a state of health with the charge and discharge cycle is H₁,H₂ ,K,Hₙ, and a state of health data sequence of a corresponding lithium battery pack with the charge and discharge cycle is [H₁,H₂,K,Hₙ], wherein

$${H}_{i} = \frac{{C}_{i}}{C} ,$$

Hᵢ is the SOH of the lithium battery pack in an i-th (i=1,2,K, n) charge and discharge cycle, n is a number of charge and discharge cycles, Cᵢ is a discharge capacity of the lithium battery pack in the i-th charge and discharge cycle, and C is a rated capacity of the lithium battery pack;

in some alternative embodiments, step (2) includes:

the change data of a voltage entropy of a single battery with the charge and discharge cycle is V_{1,r},V_{2,r},K,V_{n,r}, and the voltage entropy data sequence of the corresponding battery pack is

$$[ \begin{matrix}{V}_{1 , 1} & L & {V}_{1 , m} \\ M & L & M \\ {V}_{n , 1} & L & {V}_{n , m}\end{matrix} ] ,$$

wherein

$${V}_{i , r} = - {\sum }_{j = 1}^{{N}_{i}} {x}_{i , j , r} {log}_{2} ( {x}_{i , j , r} ) ,$$

V_{i,r} is the voltage entropy of the r-th (r=1,2,K m) battery in the i-th charge and discharge cycle, m is a number of single batteries in the battery pack, x_{i,j,r} is a voltage value of a j-th (j=1,2,K, Nᵢ) sampling point in the i-th charge and discharge cycle of the r-th battery, and Nᵢ is a total number of sampling points in the i-th charge and discharge cycle;

a change data of a mean temperature of the battery pack with the charge and discharge cycle is T₁,T₂,K,Tₙ, and a corresponding mean temperature data sequence is [T₁,T₂,K,Tₙ], wherein

$${T}_{i} = {{\sum }_{j = 1}}^{{N}_{i}} {T}_{i , j} / {N}_{i} ,$$

Tᵢ is a mean temperature of the lithium battery pack in the i-th charge and discharge cycle, and T_{i,j} is a mean temperature at the j-th sampling point in the i-th charge and discharge cycle.

In some alternative embodiments, step (3) includes:

training data sets are

$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ] ,$$

test data sets are [V_{k+1,1} L V_{k+1,m} Tₖ₊₁] and [Hₖ₊₁], a voltage entropy and a mean temperature data of the lithium battery pack of a previous k-th (k=1,K,n−1) charge and discharge cycle are used as samples, a corresponding SOH data of each charge and discharge cycle is used as a target for training, and the voltage entropy, the mean temperature, and the SOH data of the lithium battery pack of a k+1-th charge and discharge cycle are tested;

taking an absolute difference between a true value and an estimated value of an SOH of the k+1-th charge and discharge cycle as an adaptability function, a process of using the particle swarm algorithm to optimize the learning rate of the long short-term memory neural network is:

(a) initializing the particle swarm algorithm randomly, including a position, a velocity, a number of iterations, and an algorithm end condition of each particle, wherein a learning rate that needs to be optimized is mapped to the particle;

(b) using training sets

$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ]$$

for training, testing data sets [V_{k+1,1} L V_{k+1,m} Tₖ₊₁] and [Hₖ₊₁] for testing, and setting a learning rate range;

(c) bringing the position of the particle into the adaptability function to obtain an adaptability value of each particle;

(d) comparing an adaptability value of the particle at a current position with an adaptability value of a historical best position, and selecting the better one to generate an optimal solution of each particle;

(e) comparing a historical best adaptability value of the particle with an adaptability value of a global optimal position, and selecting the better one to generate the global optimal solution;

(f) updating the velocity and the position of the particle and checking whether an error meets an error requirement;

(g) repeating (c) to step (f) until the error requirement is met, and outputting a learning rate result.

In some alternative embodiments, step (4) includes:

training the training data set before a k-th charge and discharge cycle, and inputting a voltage entropy and a mean temperature data sequence [V_{k+1,1} L V_{k+1,m} Tₖ₊₁] of a lithium battery pack of a k+1-th charge and discharge cycle after the particle swarm algorithm optimizes the learning rate of the long short-term memory neural network, and an output result Hₖ₊₁ is an estimated value of an SOH of the k+1-th charge and discharge cycle.

According to another aspect of the invention, a system for estimating an SOH of a battery pack is provided, including:

a first data processing module configured to measure a state of health SOH data sequence and a characteristic data sequence of a lithium battery pack with a charge and discharge cycle, wherein the characteristic data sequence of the lithium battery pack with the charge and discharge cycle includes a change data of a terminal voltage and a temperature of a charging stage in each charge and discharge cycle;

a second data processing module configured to perform a statistical analysis on the change data of the voltage and the temperature of the charging stage in each charge and discharge cycle, and calculate a voltage entropy data sequence and a mean temperature data sequence of the lithium battery pack with the charge and discharge cycle;

an optimization module configured to execute an optimization option on a learning rate of a long short-term memory neural network using a particle swarm algorithm based on the voltage entropy data sequence, the mean temperature data sequence, and the SOH data sequence of the lithium battery pack with the charge and discharge cycle;

a model estimation module configured to establish an SOH estimation model of the long short-term memory neural network using the learning rate obtained by the particle swarm optimization, in order to estimate an SOH of the lithium battery pack using the established SOH estimation model of the long short-term memory neural network.

In some alternative embodiments, the first data processing module is configured to use the measured state of health data of the lithium battery pack as the SOH data of the lithium battery pack, the change data of a state of health with the charge and discharge cycle is H₁,H₂,K,Hₙ, and a state of health data sequence of a corresponding lithium battery pack with the charge and discharge cycle is [H₁,H₂,K,Hₙ], wherein

$${H}_{i} = \frac{{C}_{i}}{C} ,$$

Hᵢ is the SOH of the lithium battery pack in an i-th (i=1,2,K,n) charge and discharge cycle, n is a number of charge and discharge cycles, Cᵢ is a discharge capacity of the lithium battery pack in the i charge and discharge cycle, and C is a rated capacity of the lithium battery pack;

in some alternative embodiments, the second data processing module is configured to use a change data of a voltage entropy of a single battery with the charge and discharge cycle as V_{1,r},V_{2,r},K,V_{n,r}, and a voltage entropy data sequence of a corresponding battery pack is

$$[ \begin{matrix}{V}_{1 , 1} & L & {V}_{1 , m} \\ M & L & M \\ {V}_{n , 1} & L & {V}_{n , m}\end{matrix} ] ,$$

wherein

$${V}_{i , r} = - {\sum }_{j = 1}^{{N}_{i}} {x}_{i , j , r} {log}_{2} ( {x}_{i , j , r} ) ,$$

V_{i,r} is a voltage entropy of an r-th (r=1,2,K m) battery in an i-th charge and discharge cycle, m is a number of single batteries in the battery pack, is a voltage value of a j-th (j=1,2,K,Nᵢ) sampling point in the i-th charge and discharge cycle of the r-th battery, and Nᵢ is a total number of sampling points in the i-th charge and discharge cycle;

a change data of a mean temperature of the battery pack with the charge and discharge cycle is T₁,T₂,K,Tₙ, and a corresponding mean temperature data sequence is [T₁,T₂,K,Tₙ], wherein

$${T}_{i} = {{\sum }_{j = 1}}^{{N}_{i}} {T}_{i , j} / {N}_{i} ,$$

Tᵢ is a mean temperature of the lithium battery pack in an i-th charge and discharge cycle, and T_{i,j} is a mean temperature at a j-th sampling point in the i-th charge and discharge cycle.

In some alternative embodiments, the optimization module is configured to confirm training data sets are

$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ] ,$$

test data sets are [V_{k+1,1} L V_{k+1,m} Tₖ₊₁] and [Hₖ₊₁], a voltage entropy and a mean temperature data of the lithium battery pack of a previous k-th (k=1,K,n−1) charge and discharge cycle are used as samples, a corresponding SOH data of each charge and discharge cycle is used as a target for training, and the voltage entropy, the mean temperature, and the SOH data of the lithium battery pack of a k+1-th charge and discharge cycle are tested;

an absolute difference between a true value and an estimated value of an SOH of the k+1-th charge and discharge cycle is used as the adaptability function, and a process of using the particle swarm algorithm to optimize the learning rate of the long short-term memory neural network is:

(a) initializing the particle swarm algorithm randomly, comprising a position, a velocity, a number of iterations, and an algorithm end condition of each particle, wherein a learning rate that needs to be optimized is mapped to the particle;

(b) using training sets

$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ]$$

for training, testing data sets [V_{k+1,1} L V_{k+1,m} Tₖ₊₁] and [Hₖ₊₁] for testing, and setting a learning rate range;

(c) bringing the position of the particle into the adaptability function to obtain an adaptability value of each particle;

(d) comparing an adaptability value of the particle at a current position with an adaptability value of a historical best position, and selecting the better one to generate an optimal solution of each particle;

(e) comparing a historical best adaptability value of the particle with an adaptability value of a global optimal position, and selecting the better one to generate the global optimal solution;

(f) updating the velocity and the position of the particle and checking whether an error meets an error requirement;

(g) repeating (c) to step (f) until the error requirement is met, and outputting a learning rate result.

In some alternative embodiments, a model estimation module is configured to train the training data sets before the k-th charge and discharge cycle, and after the particle swarm algorithm optimizes the learning rate of the long short-term memory neural network, a voltage entropy and a mean temperature data sequence [V_{k+1,1} L V_{k+1,m} Tₖ₊₁] of a lithium battery pack of the k+1-th charge and discharge cycle are input, and an output result Hₖ₊₁ is an estimated value of SOH of the k+1-th charge and discharge cycle.

According to another aspect of the invention, a computer-readable storage medium is provided, wherein a computer program is stored thereon, and when the computer program is executed by a processor, the steps of any of the above methods are implemented.

Generally speaking, compared with the prior art, the above technical solutions conceived by the invention may achieve the following beneficial effects:

the data sequence using voltage entropy and mean temperature effectively reflects the capacity degradation of the lithium battery pack; at the same time, the use of battery pack voltage entropy may effectively simplify input and reduce the amount of calculation; the estimation accuracy of the long short-term memory neural network after the optimization option of the learning rate by particle swarm optimization is significantly improved compared with the traditional empirical method.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic flowchart of a method for estimating the state of health of a battery pack provided by an embodiment of the invention.

FIG. 2 is a diagram showing SOH data of SOH measurement of a lithium battery pack provided by an embodiment of the invention.

FIG. 3 is a comparison diagram of SOH estimation results of lithium battery packs by a lithium battery pack SOH estimation method provided by an embodiment of the invention and three other methods.

FIG. 4 is a comparison diagram of the SOH estimation errors of lithium battery packs by a lithium battery pack SOH estimation method provided by an embodiment of the invention and three other methods.

### DESCRIPTION OF THE EMBODIMENTS

In order to make the objects, technical solutions, and advantages of the invention clearer, the invention is further described in detail below in conjunction with the accompanying figures and embodiments. It should be understood that the specific embodiments described herein are only used to explain the invention, and are not intended to limit the invention. In addition, the technical features involved in the various embodiments of the invention described below may be combined with each other as long as there is no conflict with each other.

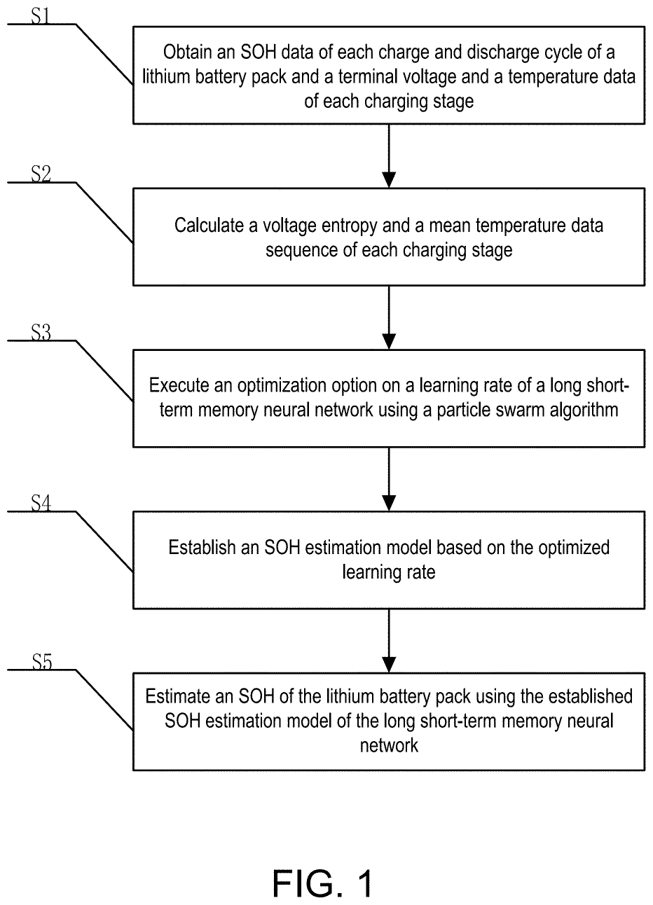

FIG. 1 is a schematic flowchart of a method for estimating the state of health of a battery pack provided by an embodiment of the invention. The method shown in FIG. 1 includes the following steps:

S1: measuring a state of health (SOH) data sequence and a characteristic data sequence of a lithium battery pack with a charge and discharge cycle, wherein the characteristic data sequence of the lithium battery pack with the charge and discharge cycle includes a change data of a terminal voltage and a temperature of a charging stage in each charge and discharge cycle;

S2: performing a statistical analysis on the change data of the terminal voltage and the temperature of the charging stage in each charge and discharge cycle, and calculating a voltage entropy data sequence and a mean temperature data sequence of the lithium battery pack with the charge and discharge cycle;

S3: executing an optimization option on a learning rate of a long short-term memory neural network using a particle swarm algorithm based on the voltage entropy data sequence, the mean temperature data sequence, and the SOH data sequence of the lithium battery pack with the charge and discharge cycle;

S4: establishing an SOH estimation model of the long short-term memory neural network using the learning rate obtained by the particle swarm optimization;

S5: estimating an SOH of the lithium battery pack using the established SOH estimation model of the long short-term memory neural network.

In an embodiment of the invention, in step S1, the measured state of health data of the lithium battery pack is the SOH data of the lithium battery pack, the change data of the state of health with the charge and discharge cycle is H₁,H₂,K,Hₙ, and the corresponding state of health data sequence is [H₁,H₂,K,Hₙ], wherein

$${H}_{i} = \frac{{C}_{i}}{C} ,$$

Hᵢ is the SOH of the lithium battery pack in the i-th (i=1,2,K,n) charge and discharge cycle, n is the number of charge and discharge cycles, Cᵢ is the discharge capacity of the lithium battery pack in the i-th charge and discharge cycle, and C is the rated capacity of the lithium battery pack;

the measured characteristic information of the lithium battery pack with the charge and discharge cycle refers to the change data of the terminal voltage and the temperature of the charging stage in each charge and discharge cycle.

In an embodiment of the invention, in step S2, the change data of the voltage entropy of a single battery with the charge and discharge cycle is V_{1,r},V_{2,r},K,V_{n,r}, and the voltage entropy data sequence of the corresponding battery pack is

$$[ \begin{matrix}{V}_{1 , 1} & L & {V}_{1 , m} \\ M & L & M \\ {V}_{n , 1} & L & {V}_{n , m}\end{matrix} ] ,$$

wherein

$${V}_{i , r} = - {\sum }_{j = 1}^{{N}_{i}} {x}_{i , j , r} {log}_{2} ( {x}_{i , j , r} ) ,$$

V_{i,r} is the voltage entropy of the r-th (r=1,2,K m) battery in the i-th charge and discharge cycle, m is the number of single batteries in the battery pack, x_{i,j,r} is the voltage value of the j-th (j=1,2,K, Nᵢ) sampling point in the i-th charge and discharge cycle of the r-th battery, and Nᵢ is the total number of sampling points in the i-th charge and discharge cycle;

the change data of a mean temperature of the battery pack with the charge and discharge cycle is T₁,T₂,K,Tₙ, and the corresponding mean temperature data sequence is [T₁,T₂,K,Tₙ], wherein

$${T}_{i} = {\sum }_{j = 1}^{N} {T}_{i , j} / {N}_{i} ,$$

Tᵢ is the mean temperature of the lithium battery pack in the i-th charge and discharge cycle, and T_{i,j} is the mean temperature at the j-th sampling point in the i-th charge and discharge cycle.

In an embodiment of the invention, in step S3, training data sets are

$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ] ,$$

test data sets are [V_{k+1,1} L V_{k+1,m} Tₖ₊₁] and [Hₖ₊₁], the voltage entropy and the mean temperature data of the lithium battery pack of the previous k-th (k=1,K,n−1) charge and discharge cycle are used as samples, the corresponding SOH data of each charge and discharge cycle is used as a target for training, and the voltage entropy, the mean temperature, and the SOH data of the lithium battery pack of the k+1-th charge and discharge cycle are tested.

Taking the absolute difference between the true value and the estimated value of the SOH of the k+1-th charge and discharge cycle as the adaptability function, the process of using the particle swarm algorithm to optimize the learning rate of the long short-term memory neural network is:

(1) initializing the particle swarm algorithm randomly, including a position, a velocity, a number of iterations, and an algorithm end condition of each particle, wherein a learning rate that needs to be optimized is mapped to the particle;

(2) using training sets

$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ]$$

for training, testing data sets [V_{k+1,1} L V_{k+1,m} Tₖ₊₁] and [Hₖ₊₁] for testing, and setting a learning rate range;

(3) bringing the position of the particle into an adaptability function to obtain an adaptability value of each particle;

(4) comparing an adaptability value of the particle at a current position with an adaptability value of a historical best position, and selecting the better one to generate an optimal solution of each particle;

(5) comparing a historical best adaptability value of the particle with an adaptability value of a global optimal position, and selecting the better one to generate the global optimal solution;

(6) updating the velocity and the position of the particle and checking whether an error meets an error requirement;

(7) repeating step (3) to step (6) until the error requirement is met, and a learning rate result is output.

In particular, the particle swarm algorithm is a global random search algorithm based on swarm intelligence, the algorithm randomly generates a certain number of particles in the d-dimensional space and uses position l_{q,d,H}(q=1, 2,K, M) and velocity v_{q,d,H} to represent the characteristics of the particles, M is the number of particles, H is the current iteration number, and the end condition is set to the error being less than 1e−4, and usually includes four operation processes: obtaining the adaptability value of each particle, generating the optimal solution for each particle and the global optimal solution, and updating the particle velocity and position;

the criteria for generating the optimal solution of each particle and the global optimal solution are as follows: selecting the position corresponding to the maximum adaptability value in all the historical adaptability values of each particle as the optimal solution of each particle, comparing the historical maximum adaptability value of each particle with the adaptability value corresponding to the global optimal position, and taking the position corresponding to the maximum adaptability value as the global optimal solution;

the particle velocity and position are updated by the following formulas:

v_{q,d,h+1}=ωv_{q,d,H}+c₁r₁(p_{q,d,H}−l_{q,d,H})+c₂r₂(p_{q,d,H,g}−l_{q,d,H})

l_{q,d,H+1}=l_{q,d,H}+v_{q,d,H+1}

in particular, ω is inertia weight, c₁ and c₂ are called acceleration constants, r₁ and r₂ are random numbers in (0, 1) , v_{q,d,H} and l_{q,d,H} represent the current velocity and position of the particle q in the d dimensional space after H iterations, and p_{q,d,H} and P_{q,d,H,g} respectively represent the current individual optimal solution and the global optimal solution of the particle q in the d dimensional space after H iterations.

In an embodiment of the invention, in step S4, the method for estimating the SOH of the lithium battery pack using the long short-term memory neural network after optimization by the particle swarm algorithm is: training the training data set before the k-th charge and discharge cycle, and after the particle swarm algorithm optimizes the learning rate of the long short-term memory neural network, the voltage entropy and the mean temperature data sequence [V_{k+1,1} L V_{k+1,m} Tₖ₊₁] of the k+1-th charge and discharge cycle are input, and the output result Hₖ₊₁ is the estimated value of the k+1-th charge and discharge cycle SOH.

In order to demonstrate the process and estimation performance of the method for estimating the state of health of a battery pack provided by the invention, one example is described herein.

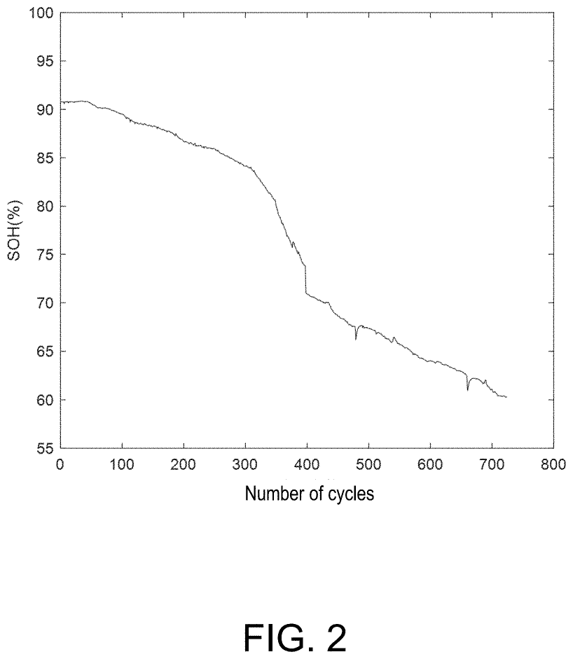

In the laboratory, six single batteries of a certain brand with a rated capacity of 2.4 Ah and a discharge capacity of 2.35 Ah were connected in series to form a pack, and the battery pack was charged and discharged in an experiment. During the charging stage, the batteries were charged with a constant current of 1.2 A. When the battery pack terminal voltage reached 24.9 V, the terminal voltage was kept unchanged to continue charging. When the charging current dropped to 48 mA, the charging ended. After being left for 10 seconds, discharge was performed at a constant current of 2 A. When the terminal voltage of the battery pack dropped to 19.3 V, the discharge ended. The battery pack was repeatedly charged and discharged. When the discharge capacity of the battery pack was less than 60% of the rated capacity, the experiment ended. The experiment lasted for 83 days. FIG. 2 shows the change of the SOH of the lithium battery pack with the charge and discharge cycle. The specific operation steps are as follows:

(1) the voltage entropy data sequence, the mean temperature data sequence, and the SOH data sequence of the lithium battery pack were extracted based on the lithium battery pack data measured in the laboratory, the voltage entropy, the mean temperature, and corresponding SOH in one charge and discharge cycle were a set of data, the data from days 1 to 82 were used as the training data, any set of data from day 83 was used as the test set, and optimization option was performed on the learning rate of the long short-term memory neural network using particle swarm algorithm;

in the particle swarm algorithm, the population size and the number of iterations were set to 30 and 500 respectively, the position and the velocity of the particles were randomly initialized, and the learning rate was set to between 0.0001 and 0.1. When the estimated value and the difference of the long short-term memory neural network were less than 0.0001 three times in a row, the algorithm ended. The width factor of the optimization option was 0.0007.

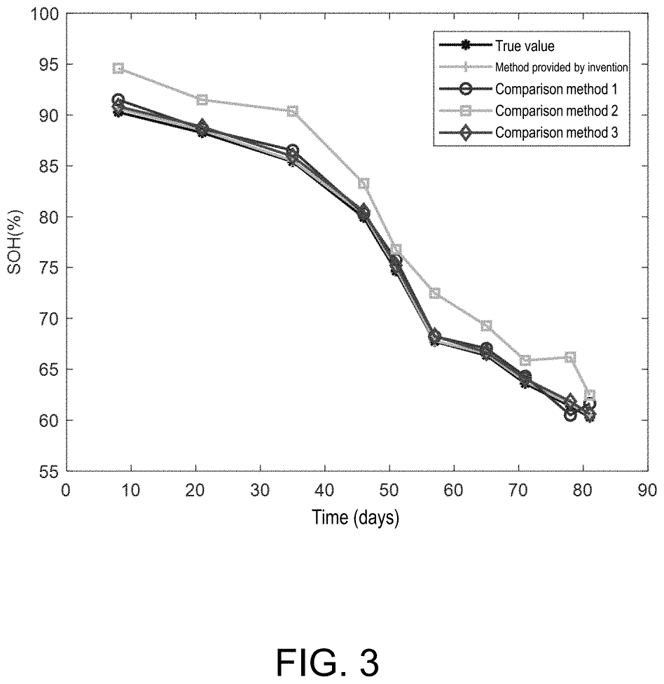

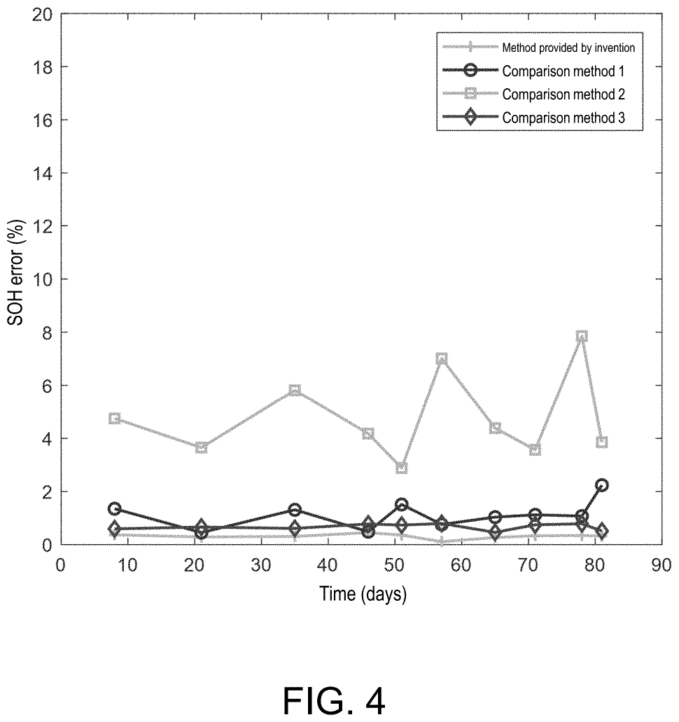

(2) data from days 8, 21, 35, 46, 51, 57, 65, 71, 78, and 81 was randomly selected using 0.0007 as the learning rate in the long short-term memory neural network as the test set to estimate the SOH of the lithium battery pack, and the corresponding training sets were respectively 1-59, 1-155, 1-264, 1-353, 1-392, 1-471, 1-532, 1-626, 1-697, 1-728 set data. At the same time, three common methods were respectively used to compare with the method provided by the invention. Table 1 shows the comparison methods used, FIG. 3 and FIG. 4 respectively show the comparison graphs and error comparison graphs of the estimation results of the different methods, and Table 2 statistically shows the average error and maximum error of the estimation results of the different methods.

TABLE 1

| Method | Input | Estimation method |
|---|---|---|
| Method provided | Voltage entropy and | Long short-term memory |
| by invention | mean temperature | neural network after |
| | | optimization by particle |
| | | swarm algorithm |
| Comparison | Voltage and mean | Long short-term memory |
| method 1 | temperature | neural network after |
| | | optimization by particle |
| | | swarm algorithm |
| Comparison | Voltage entropy and | BP neural network |
| method 2 | mean temperature | |
| Comparison | Voltage entropy | Long short-term memory |
| method 3 | | neural network after |
| | | optimization by particle |
| | | swarm algorithm |

TABLE 2

| | Method provided | | Comparison | | Comparison | | Comparison | |
|---|---|---|---|---|---|---|---|---|
| | by invention | | method 1 | | method 2 | | method 3 | |
| | Average | Maximum | Average | Maximum | Average | Maximum | Average | Maximum |
| | error (%) | error (%) | error (%) | error (%) | error (%) | error (%) | error (%) | error (%) |
| Battery | 0.31 | 0.45 | 1.13 | 2.24 | 4.79 | 6.85 | 0.66 | 0.79 |
| pack | | | | | | | | |

It may be seen from the comparison chart of the estimation results and the error comparison chart that the estimated value of the SOH estimation method of the lithium battery pack provided by the invention is more stable with the true value, and the same conclusion may be drawn from Table 2. The average error and maximum error of the SOH estimation method of the lithium battery pack provided by the invention are both lower than comparison method 1 and comparison method 3, which shows that the combination of voltage entropy and mean temperature may better reflect the degradation of lithium battery pack capacity. The average error and the maximum error of comparison method 2 are significantly higher than the SOH estimation method provided by the invention. This explains the high estimation accuracy of the long short-term memory neural network after optimization by the particle swarm algorithm. This shows that the method for estimating the state of health of a lithium battery pack provided by the invention has advantages such as simple operation, small error, and high accuracy.

It should be noted that, according to implementation needs, each step/component described in the present application may be split into more steps/components, or two or a plurality of steps/components or partial operations of the steps/components may be combined into new steps/components to achieve the object of the invention.

It is easy for those skilled in the art to understand that the above are only preferred embodiments of the invention and are not intended to limit the invention. Any modification, equivalent replacement, and improvement made within the spirit and principles of the invention should be included in the protection scope of the invention.

What is claimed is:

1. A method for estimating a state of health of a battery pack, comprising:
(1) measuring a state of health SOH data sequence and a characteristic data sequence of a lithium battery pack with a charge and discharge cycle, wherein the characteristic data sequence of the lithium battery pack with the charge and discharge cycle comprises a change data of a terminal voltage and a temperature of a charging stage in each charge and discharge cycle;
(2) performing a statistical analysis on the change data of the voltage and the temperature of the charging stage in each charge and discharge cycle, and calculating a voltage entropy data sequence and a mean temperature data sequence of the lithium battery pack with the charge and discharge cycle;
(3) executing an optimization option on a learning rate of a long short-term memory neural network using a particle swarm algorithm based on the voltage entropy data sequence, the mean temperature data sequence, and the SOH data sequence of the lithium battery pack with the charge and discharge cycle;
(4) establishing an SOH estimation model of the long short-term memory neural network using the learning rate obtained by the particle swarm optimization, in order to estimate an SOH of the lithium battery pack using the established SOH estimation model of the long short-term memory neural network.

2. The method of claim 1, wherein step (1) comprises:
the measured state of health data of the lithium battery pack used for measurement is the SOH data of the lithium battery pack, a change data of a state of health with the charge and discharge cycle is H₁,H₂,K,Hₙ , and a state of health data sequence of a corresponding lithium battery pack with the charge and discharge cycle is [H₁,H₂,K,Hₙ], wherein
$${H}_{i} = \frac{{C}_{i}}{C} ,$$
Hᵢ is an SOH of the lithium battery pack in an i-th (i=1,2,K,n) charge and discharge cycle, n is a number of charge and discharge cycles, Cᵢ is a discharge capacity of the lithium battery pack in the i-th charge and discharge cycle, and C is a rated capacity of the lithium battery pack.

3. The method of claim 2, wherein step (2) comprises:
a change data of a voltage entropy of a single battery with the charge and discharge cycle is V_{1,r},V_{2,r},K,V_{n,r}, and a voltage entropy data sequence of a corresponding battery pack is
$$[ \begin{matrix}{V}_{1 , 1} & L & {V}_{1 , m} \\ M & L & M \\ {V}_{n , 1} & L & {V}_{n , m}\end{matrix} ] ,$$
wherein
$${V}_{i , r} = - {\sum }_{j = 1}^{{N}_{i}} {x}_{i , j , r} {log}_{2} ( {x}_{i , j , r} ) ,$$
V_{i,r} is a voltage entropy of an r-th (r=1,2,K m) battery in the i-th charge and discharge cycle, m is a number of single batteries in the battery pack, x_{i,j,r} is a voltage value of a j-th (j=1,2,K, Nᵢ) sampling point in the i-th charge and discharge cycle of the r-th battery, and Nᵢ is a total number of sampling points in the i-th charge and discharge cycle;
a change data of a mean temperature of the battery pack with the charge and discharge cycle is T₁,T₂,K,Tₙ, and a corresponding mean temperature data sequence is [T₁,T₂,K,Tₙ], wherein
$${T}_{i} = {\sum }_{j = 1}^{N} {T}_{i , j} / {N}_{i} ,$$
Tᵢ is a mean temperature of the lithium battery pack in the i-th charge and discharge cycle, and T_{i,j} is a mean temperature at the j-th sampling point in the i-th charge and discharge cycle.

4. The method of claim 3, wherein step (3) comprises:
training data sets are
$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ] ,$$
test data sets are [V_{k+1,1} L V_{k+1,m} Tₖ₊₁] and [Hₖ₊₁], a voltage entropy and a mean temperature data of the lithium battery pack of a previous k-th (k=1,K,n−1) charge and discharge cycle are used as samples, a corresponding SOH data of each charge and discharge cycle is used as a target for training, and the voltage entropy, the mean temperature, and the SOH data of the lithium battery pack of a k+1-th charge and discharge cycle are tested;
taking an absolute difference between a true value and an estimated value of an SOH of the k+1-th charge and discharge cycle as an adaptability function, and a process of using the particle swarm algorithm to optimize the learning rate of the long short-term memory neural network is:
(a) initializing the particle swarm algorithm randomly, comprising a position, a velocity, a number of iterations, and an algorithm end condition of each particle, wherein a learning rate that needs to be optimized is mapped to the particle;
(b) using training sets
$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ]$$
for training, testing data sets [V_{k+1,1} L V_{k+1,m} Tₖ₊₁] and [Hₖ₊₁] for testing, and setting a learning rate range;
(c) bringing the position of the particle into the adaptability function to obtain an adaptability value of each particle;
(d) comparing an adaptability value of the particle at a current position with an adaptability value of a historical best position, and selecting the better one to generate an optimal solution of each particle;
(e) comparing a historical best adaptability value of the particle with an adaptability value of a global optimal position, and selecting the better one to generate the global optimal solution;
(f) updating the velocity and the position of the particle and checking whether an error meets an error requirement;
(g) repeating (c) to step (f) until the error requirement is met, and outputting a learning rate result.

5. The method of claim 4, wherein step (4) comprises:
training the training data sets before the k-th charge and discharge cycle, and inputting a voltage entropy and a mean temperature data sequence [V_{k+1,1} L V_{k+1,m} Tₖ₊₁] of the lithium battery pack of the k+1-th charge and discharge cycle after the particle swarm algorithm optimizes the learning rate of the long short-term memory neural network, and an output result Hₖ₊₁ is an estimated value of an SOH of the k+1-th charge and discharge cycle.

6. A system for estimating a state of health of a battery pack, comprising:
a first data processing module configured to measure a state of health SOH data sequence and a characteristic data sequence of a lithium battery pack with a charge and discharge cycle, wherein the characteristic data sequence of the lithium battery pack with the charge and discharge cycle comprises a change data of a terminal voltage and a temperature of a charging stage in each charge and discharge cycle;
a second data processing module configured to perform a statistical analysis on the change data of the terminal voltage and the temperature of the charging stage in each charge and discharge cycle, and calculate a voltage entropy data sequence and a mean temperature data sequence of the lithium battery pack with the charge and discharge cycle;
an optimization module configured to execute an optimization option on a learning rate of a long short-term memory neural network using a particle swarm algorithm based on the voltage entropy data sequence, the mean temperature data sequence, and the SOH data sequence of the lithium battery pack with the charge and discharge cycle;
a model estimation module configured to establish an SOH estimation model of the long short-term memory neural network using the learning rate obtained by the particle swarm optimization, in order to estimate an SOH of the lithium battery pack using the established SOH estimation model of the long short-term memory neural network.

7. The system of claim 6, wherein the first data processing module is configured to use the measured state of health data of the lithium battery pack as the SOH data of the lithium battery pack, a change data of a state of health with the charge and discharge cycle is H₁,H₂,K,Hₙ, and a state of health data sequence of a corresponding lithium battery pack with the charge and discharge cycle is [H₁,H₂,K,Hₙ], wherein
$${H}_{i} = \frac{{C}_{i}}{C} ,$$
Hᵢ is the SOH of the lithium battery pack in an i-th (i=1, 2,K,n) charge and discharge cycle, n is a number of charge and discharge cycles, Cᵢ is a discharge capacity of the lithium battery pack in the i-th charge and discharge cycle, and C is a rated capacity of the lithium battery pack.

8. The system of claim 7, wherein the second data processing module is configured to use a change data of a voltage entropy of a single battery with the charge and discharge cycle as V_{1,r},V_{2,r}K,V_{n,r}, and a voltage entropy data sequence of a corresponding battery pack is
$$[ \begin{matrix}{V}_{1 , 1} & L & {V}_{1 , m} \\ M & L & M \\ {V}_{n , 1} & L & {V}_{n , m}\end{matrix} ] ,$$
wherein
$${V}_{i , r} = - {\sum }_{j = 1}^{{N}_{i}} {x}_{i , j , r} {log}_{2} ( {x}_{i , j , r} ) ,$$
V_{i,r} is a voltage entropy of an r-th (r=1,2,K m) battery in the i-th charge and discharge cycle, m is a number of single batteries in the battery pack, x_{i,j,r} is a voltage value of a j-th (j=1,2,K, Nᵢ) sampling point in the i-th charge and discharge cycle of the r-th battery, and Nᵢ is a total number of sampling points in the i-th charge and discharge cycle;
a change data of a mean temperature of the battery pack with the charge and discharge cycle is T₁,T₂,K,Tₙ, and a corresponding mean temperature data sequence is [T₁,T₂,K,Tₙ], wherein
$${T}_{i} = {\sum }_{j = 1}^{N} {T}_{i , j} / {N}_{i} ,$$
Tᵢ is a mean temperature of the lithium battery pack in the i-th charge and discharge cycle, and T_{i,j} is a mean temperature at the j-th sampling point in the i-th charge and discharge cycle.

9. The system of claim 8, wherein the optimization module is configured to confirm training data sets are
$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ] ,$$
test data sets are [V_{k+1,1} L V_{k+1,m} Tₖ₊₁] and [Hₖ₊₁], a voltage entropy and a mean temperature data of the lithium battery pack of a previous k-th (k=1,K,n−1) charge and discharge cycle are used as samples, a corresponding SOH data of each charge and discharge cycle is used as a target for training, and the voltage entropy, the mean temperature, and the SOH data of the lithium battery pack of a k+1-th charge and discharge cycle are tested;
taking an absolute difference between a true value and an estimated value of an SOH of the k+1-th charge and discharge cycle as an adaptability function, and a process of using the particle swarm algorithm to optimize the learning rate of the long short-term memory neural network is:
(a) initializing the particle swarm algorithm randomly, including a position, a velocity, a number of iterations, and an algorithm end condition of each particle, wherein a learning rate that needs to be optimized is mapped to the particle;
(b) using training sets
$$[ \begin{matrix}{V}_{1 , 1} & L & {V}_{1 , m} & {T}_{1} \\ {V}_{2 , 1} & L & {V}_{2 , m} & {T}_{2} \\ M & L & M & M \\ {V}_{k , 1} & L & {V}_{k , m} & {T}_{k}\end{matrix} ] and [ \begin{matrix}{H}_{1} \\ M \\ {H}_{k}\end{matrix} ]$$
for training, testing data sets [V_{k+1,1} L V_{k+1,m} Tₖ₊₁] and [Hₖ₊₁] for testing, and setting a learning rate range;
(c) bringing the position of the particle into an adaptability function to obtain an adaptability value of each particle;
(d) comparing an adaptability value of the particle at a current position with an adaptability value of a historical best position, and selecting the better one to generate an optimal solution of each particle;
(e) comparing a historical best adaptability value of the particle with an adaptability value of a global optimal position, and selecting the better one to generate the global optimal solution;
(f) updating the velocity and the position of the particle and checking whether an error meets an error requirement;
(g) repeating (c) to step (f) until the error requirement is met, and outputting a learning rate result.

10. A computer-readable storage medium, with a computer program stored thereon, wherein the computer program implements the steps of the method of claim 1 when the computer program is executed by a processor.

11. A computer-readable storage medium, with a computer program stored thereon, wherein the computer program implements the steps of the method of claim 2 when the computer program is executed by a processor.

12. A computer-readable storage medium, with a computer program stored thereon, wherein the computer program implements the steps of the method of claim 3 when the computer program is executed by a processor.

13. A computer-readable storage medium, with a computer program stored thereon, wherein the computer program implements the steps of the method of claim 4 when the computer program is executed by a processor.

14. A computer-readable storage medium, with a computer program stored thereon, wherein the computer program implements the steps of the method of claim 5 when the computer program is executed by a processor.
